(19) United States
(12) Patent Application Publication
(10) Pub. No.: US 2009/0120677 A1
(43) Pub. Date: May 14, 2009

(54) WIRING SUBSTRATE AND ASSOCIATED MANUFACTURING METHOD

(75) Inventors: Toshihiro NOMURA, Gifu (JP); Hiroshi SEGAWA, Gifu (JP); Yoshifumi MIYAZAWA, Gifu (JP); Katsuya OKUMURA, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignees: IBIDEN CO., LTD, Ogaki-shi (JP); OCTEC INC., Shinjuku-ku (JP)

(21) Appl. No.: 12/205,453

(22) Filed: Sep. 5, 2008

Related U.S. Application Data
(60) Provisional application No. 60/988,895, filed on Nov. 19, 2007.

(30) Foreign Application Priority Data
Sep. 5, 2007 (JP) 2007-230443

(51) Int. Cl. H05K 1/11; H05K 3/10

(52) U.S. Cl. 174/262; 29/846

(57) ABSTRACT

A wiring substrate for mounting electronic parts and a method for manufacturing the same are provided. The wiring substrate includes a substrate that includes a first surface, a second surface and a plurality of through-holes that extend through the substrate from the first surface to the second surface so as to define a plurality of inner walls respectively. The wiring substrate further includes an external conductor that is formed on at least one of the first surface or the second surface of the substrate. A through-hole conductor is formed on one of the plurality of inner walls so as to define a through-hole conductor space and so as to be electrically connected to the external conductor. Also included is a conductive post with first and second post ends, the first post end being positioned in the through-hole conductor space such that the first post end is in contact with and is electrically connected to the through-hole conductor, and the second post end projects out of the conductor space.

### RELATED APPLICATIONS

The present application claims priority to Japanese Patent Application No. 2007-230443, filed Sep. 5, 2007 and U.S. Provisional Application No. 61/988,895, filed Nov. 19, 2007, the entire contents of each of which are hereby incorporated by reference.

### TECHNICAL FIELD

A wiring substrate and a manufacturing method for mounting electronic parts such as an IC are provided. In particular, a wiring substrate configured to mount a low-k semiconductor with a particularly low effective permittivity, a switching element, a power system semiconductor element, or the like is provided.

### DESCRIPTION OF THE RELATED ART

Japanese Unexamined Patent Application Publication No. 2004-228403 describes a switching power device that is reduced in size and thickness and that prevents noise that is caused when a switching element is switched on from affecting the control IC. This document describes that an electrode on the back surface of a power semiconductor element is connected and fixed to a conductor pattern of an insulation substrate. A wiring substrate is disposed in a position opposite to the insulation substrate. A wiring pattern formed in the surface of the wiring substrate opposite to the insulation substrate and an electrode in the upper surface of the power semiconductor element are connected through an electrically conductive post. For conventional semiconductor-mounting substrates, penetrating holes are opened on both surfaces of the substrate and, by inserting a copper post, an electrical connection between the copper post and the conductors of the double-sided substrate are established with the use of an electrically conductive adhesive.

### SUMMARY OF THE INVENTION

In one exemplary aspect, a wiring substrate for mounting electronic parts is provided. The wiring substrate includes a substrate that includes a first surface, a second surface, and a plurality of through-holes that extend through the substrate from the first surface to the second surface so as to define a plurality of inner walls respectively. The wiring substrate further includes an external conductor formed on at least one of the first surface or the second surface of the substrate. A through-hole conductor is formed on one of the plurality of inner walls of the through-holes so as to define a through-hole conductor space and so as to be electrically connected to the external conductor. Also included is a conductive post having first and second post ends, the first post end being positioned in the through-hole conductor space defined by the through-hole conductor such that the first post end is in contact with and is electrically connected to the through-hole conductor, and the second post end is projecting out of the conductor space.

A manufacturing method of a wiring substrate is provided in another exemplary aspect. The method includes forming a through-hole conductor on an inner wall of a through-hole that has been formed in a substrate. A column-shaped projection part is formed by punching the column-shaped projection part out of a conductive base material such that the column-shaped projection part remains connected to the base material. A position of the projection part and a through-hole opening defined by the through-hole conductor of the substrate are matched. A column-shaped post is formed by punching out the column-shaped projection part from the base material while simultaneously pressing the column-shaped post into the through-hole opening defined by the through-hole conductor of the substrate. An end part of the column-shaped post that has been pressed into the through-hole opening defined by the through-hole conductor is solder-joined to the through-hole conductor.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional drawing that illustrates an example configuration of a wiring substrate according to an exemplary aspect of the present invention.

FIG. 2 is a cross-sectional drawing that illustrates an example configuration of an electronic circuit package using the wiring substrate according to an exemplary aspect of the present invention.

FIG. 3 is a plan view of the electronic circuit package illustrated in FIG. 2.

FIG. 4A is a cross-sectional drawing that illustrates a state in which a base material is sandwiched between a punch and a die.

FIG. 4B is a cross-sectional drawing that illustrates a state in which the punch has been pushed into the base material.

FIG. 4C is a cross-sectional drawing that illustrates a state in which a substrate is placed between the base material and the die.

FIG. 4D is a cross-sectional drawing that illustrates a state in which metal posts have been punched out and pressed into through-holes.

FIG. 4E is a cross-sectional drawing that illustrates a step of aligning the end surfaces of the metal posts.

FIG. 4F is a cross-sectional drawing of a wiring substrate where a solder was formed at the end surfaces of the metal posts.

FIG. 5 is a cross-sectional drawing that illustrates an example of a punch for forming a metal post.

FIG. 6 is a partial cross-sectional drawing that illustrates an example configuration of the end surface of the metal post.

### DETAILED DESCRIPTION

A wiring substrate to mount electronic parts such as semiconductor elements must be durable against repetitive actions and repetitive temperature volatilities and must stably maintain electrical connections and insulation as well as support for parts. Circuits handling large power capacities, such as a switching power supply or a semiconductor module including a power semiconductor element (e.g. an IGBT (Insulated Gate Bipolar Transistor)) must be especially durable to high heat-discharging properties and repetitive heat cycles. Furthermore, along with the decreasing size of devices, there is a high demand for the prevention of malfunctions caused by noise by reducing such generated noise.

The switching power device described above with respect to Japanese Unexamined Patent Application Publication No. 2004-228403 includes several problems. In the described structure, the conductor of the double-sided substrate and the copper post that has been inserted through the penetrating hole are electrically conductive via the conductive adhesive. This configuration results in low long term reliability of the electrical connection against changes such as temperature or humidity caused by different thermal expansion coefficients among the electrically conductive adhesive and copper post as well as the conductor of the substrate. The low reliability is due to, for example, separation between the copper post and the electrically conductive resin or the occurrence of cracks in the electrically conductive resin. Also, due to the joining between different kinds of materials (that is, between a resin and a metal), the connection resistance is high and the heat conductivity is low.

A wiring substrate and a manufacturing method related to exemplary aspects of the present invention are described with reference to the figures. The same symbols are given to the same or equivalent portions in the drawings and the descriptions are not repeated. The size of each part in each drawing has been changed appropriately to facilitate understanding and may be different from the proportional ratio of the actual size.

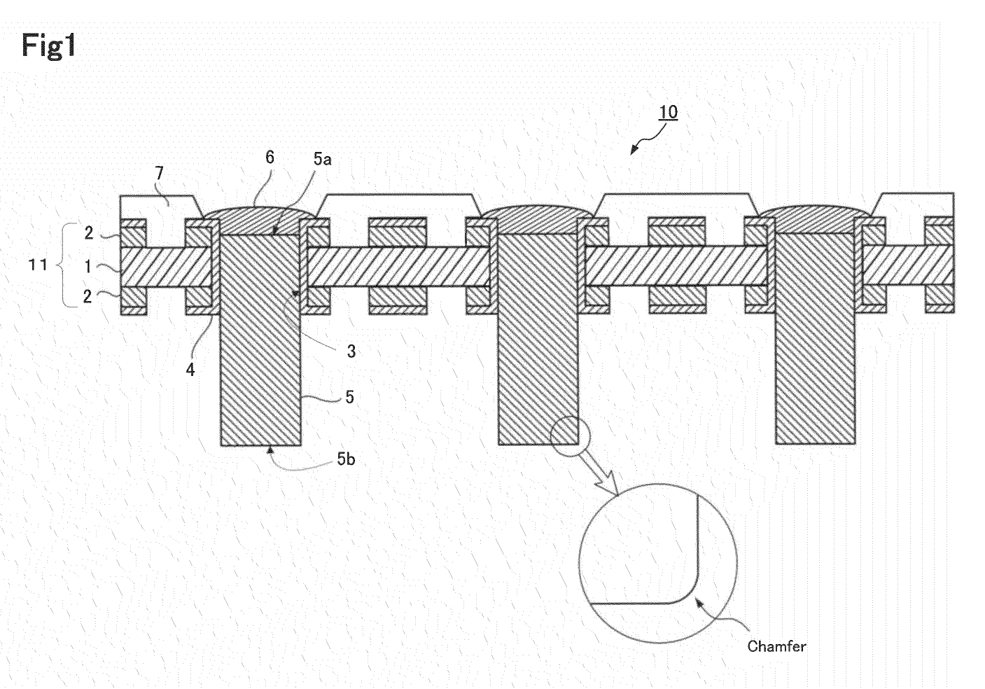

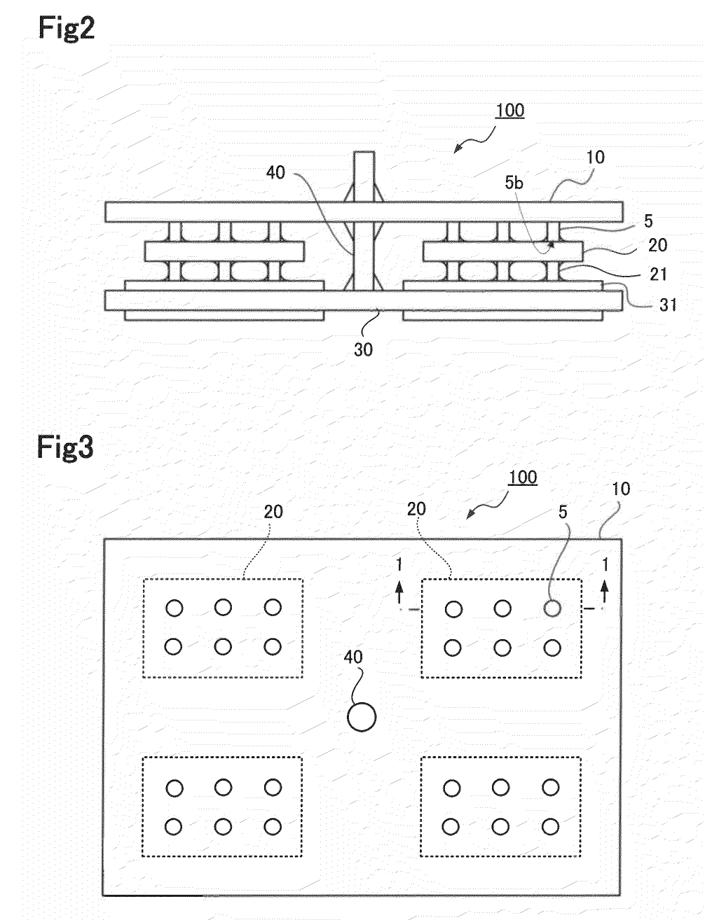

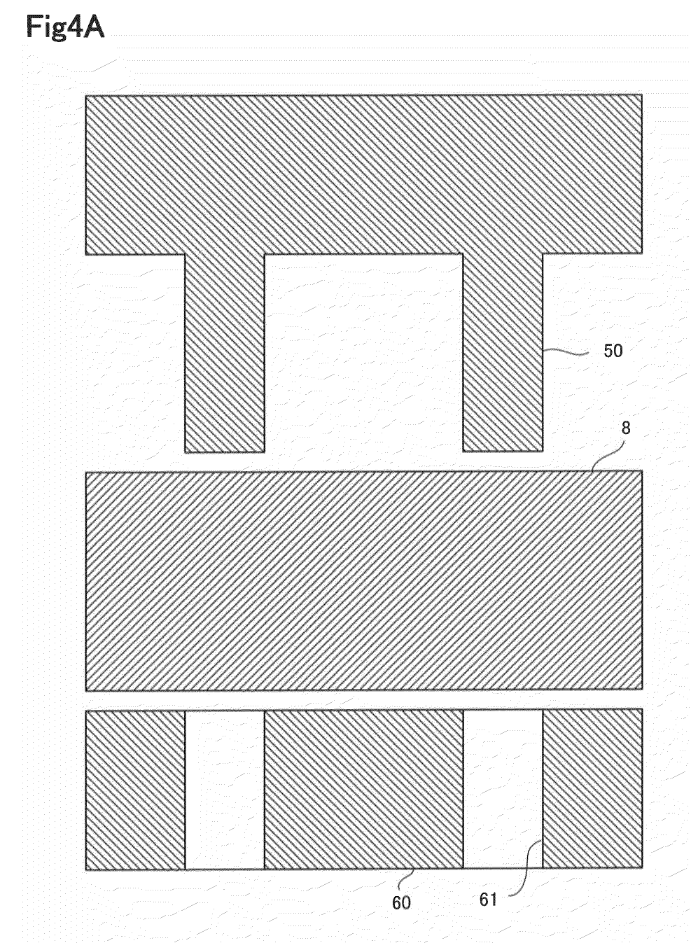

FIG. 1 is a cross-sectional drawing of a wiring substrate related to an exemplary aspect of the present invention. FIG. 2 is a cross-sectional drawing that illustrates an example configuration of an electronic circuit package in which a semiconductor chip has been mounted using the wiring substrate in FIG. 1. FIG. 3 is a plan view of an electronic circuit package shown in FIG. 2. As shown schematically in FIG. 2, in an electronic circuit package 100, a semiconductor chip 20 is soldered to a metal post 5 of a wiring substrate 10. The semiconductor chip 20 is also connected to a power supply and a grounding conductor 31 via a metal post 21 on a side of the electronic circuit package 100 opposite to the wiring substrate 10. A substrate 30 that supports the power supply and the grounding conductor 31 is supported by a support column 40, as is the wiring substrate 10.

As shown in FIG. 2 and FIG. 3, a plurality of semiconductor chips 20 are connected to the wiring substrate 10. Power is supplied to the semiconductor chips 20 from the power supply and the grounding conductor 31. The wiring substrate 10 forms a circuit by electrically connecting the semiconductor chips 20. Power semiconductor elements (e.g. IGBT element, power MOSFET (Metal Oxide Semiconductor Field Effect Transistor)) are examples of possible semiconductor chips. FIG. 1 is a cross-section of wiring substrate 10 taken along the line 1-1 in FIG. 3. As can be seen in FIG. 1, a plurality of metal posts 5 may be connected to one electrode of a semiconductor element 20. As for the electrode of a semiconductor element, there is, for example, an emitter electrode or collector electrode (an electrode connected to the ground).

As shown in FIG. 1, metal posts 5 have been inserted (implanted) into through-holes 3 of the wiring substrate 10. Conductors such as wires 2 that are formed of a copper film, for example, are formed on both surfaces of the substrate material 1. For convenience, the substrate material 1 and the wires 2 are referred to as substrate 11 throughout the description that follows. A conductor 4, such as a plated film of copper, for example, is formed on the side wall of the through-hole 3 that penetrates through the substrate 11. The conductor 4 (also referred to as through-hole conductor 4) extends over and covers the wires 2 and thereby is electrically connected to the wires 2. A metal post 5 is inserted into the through-hole 3, and both the conductor 4 and the metal post 5 are electrically connected through direct contact. One of the end surfaces 5a of the metal post 5 is positioned in the through-hole conductor 4 and the other end surface 5b of the metal post 5 projects from the wiring substrate 10. Solder resists 7 are formed on the surface of the wiring substrate 10 and a solder 6 is formed on the end surface 5a of the metal post 5 that is positioned in the through-hole conductor 4 so as to connect the metal post 5 and the surrounding conductor 4.

The metal post 5 is column-shaped and the cross section thereof can be the same shape as the cross section of the internal space (through-hole conductor space) defined by the through-hole conductor 4. For example, if the cross section of (the internal space/through-hole conductor space defined by) the through-hole conductor 4 is circular in shape, the metal post 5 can also be cylindrically shaped and can also have a circular cross section. The metal post 5 and the through-hole conductor 4 are tightly fitted such that the metal post 5 and the through-hole conductor 4 are in face-to-face contact. Even if there is a partial gap between the metal post 5 and the through-hole conductor 4, the solder 6 can be inserted so as to fill in the gap.

As can be seen in the partially enlarged portion of FIG. 1, in one exemplary aspect, the outer periphery of the end surface 5b of the metal post 5, which projects from the wiring substrate 10, is chamfered (subjected to R-process).

The metal post 5 and the through-hole conductor 4 come into face-to-face contact and, even if there is any gap, because the solder 6 can fill the gap, the connection resistance is small. As an example, in cases of in which both conductors include the same kind of metal as their main component, the resistance is extremely small. Furthermore, the metal post 5 and the through-hole conductor 4 are in face-to-face metal-against-metal contact, and hence the heat conductivity is high.

As shown in FIG. 2, the semiconductor chip 20 is connected to the end surface 5b of the metal post 5, which projects from the wiring substrate 10. In one exemplary aspect, the end surfaces 5b of the plurality of metal posts 5 that are to be joined to at least one semiconductor chip 20 are on a single plane. In this example, the semiconductor chip 20 and the wires 2 (copper film, for example) of the wiring substrate 10 are electrically connected through the metal post 5 and the through-hole conductor 4. As a result, the electrical resistance and the heat resistance between the semiconductor chip 20 and the wires 2 can be extremely small. Moreover, the metal post 5 and the through-hole conductor 4 are in face-to-face metal-against-metal contact, thus allowing for a stable heat cycle, etc.

Normally, the thermal expansion coefficients of the semiconductor chip 20 and the wiring substrate 10 are different, and even if the heat conductivity of the metal post 5 and the through-hole conductor 4 is high, the temperature gradient rises between the semiconductor chip 20 and the wiring substrate 10. Therefore, the resultant thermal expansion distortions of the semiconductor chip 20 and the wiring substrate 10 are different. Because the metal post 5 connecting the semiconductor chip 20 and the wiring substrate 10 is formed from a metal having a certain height, the metal post 5 changes its shape to absorb the difference in distortion so that the heat stress being applied to the semiconductor chip 20 and the wiring substrate 10 is mitigated.

As described above, regarding the wiring substrate 10 of the present embodiment, because the metal post 5 and the through-hole conductor 4 are tightly fitted and the metal post 5 and the through-hole conductor 4 are in face-to-face contact, the electrical resistance and the heat resistance in between these parts are small, thus allowing for a stable heat cycle, etc. As a result, the reliability of the electrical conductivity between the metal post 5 and the through-hole conductor 4 can be maintained for a long period of time. In addition, because a solder is applied to the end surface 5a of the metal post 5 that is in the through-hole conductor 4, the metal post 5 can be kept from being separated from the through-hole conductor 4.

Moreover, the end surfaces 5b of the metal posts 5 that project from the wiring substrate 10 can be on a single plane and the terminal of the semiconductor chip 20 can be subjected to soldering under the same conditions. As a result, the efficiency ratios of the electrical conductivity and the heat conductivity can be high. Furthermore, in this example, due to the connection between the metal post 5 and the through-hole conductor 4 being between identical materials, the connection resistance is lowered.

In one example aspect, the end surface 5b of the metal post 5 on the semiconductor chip 20 side of the wiring substrate 10 is parallel to the electrode surface of the semiconductor chip 20, and the end surface 5b of each metal post 5 of the wiring substrate 10 is on a single plane. In this example, the electrodes of the metal post 5 and the semiconductor chip 20 can more easily make metal to metal contact.

If the semiconductor chip 20 and the metal post 5 are connected using a solder, for example, the end surface 5b of each metal post 5 on the semiconductor chip 20 side does not have to be on a single plane with respect to the electrode surface of the semiconductor chip 20. This is because the solder can be filled in to realize electrical conductivity between the metal posts 5 and the electrode even if there is a distance gap between the metal post 5 and the electrode.

As noted above and as can be seen in FIG. 1, in one exemplary aspect, the outer periphery of the end surface 5b of the metal post 5 on the semiconductor chip 20 side of the wiring substrate 10 can be chamfered (subjected to R-process).

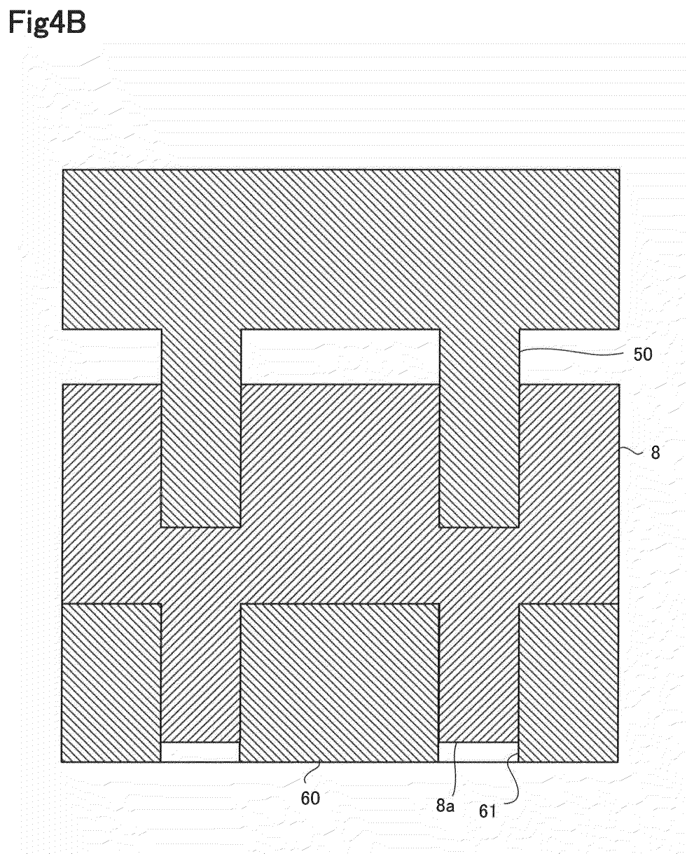

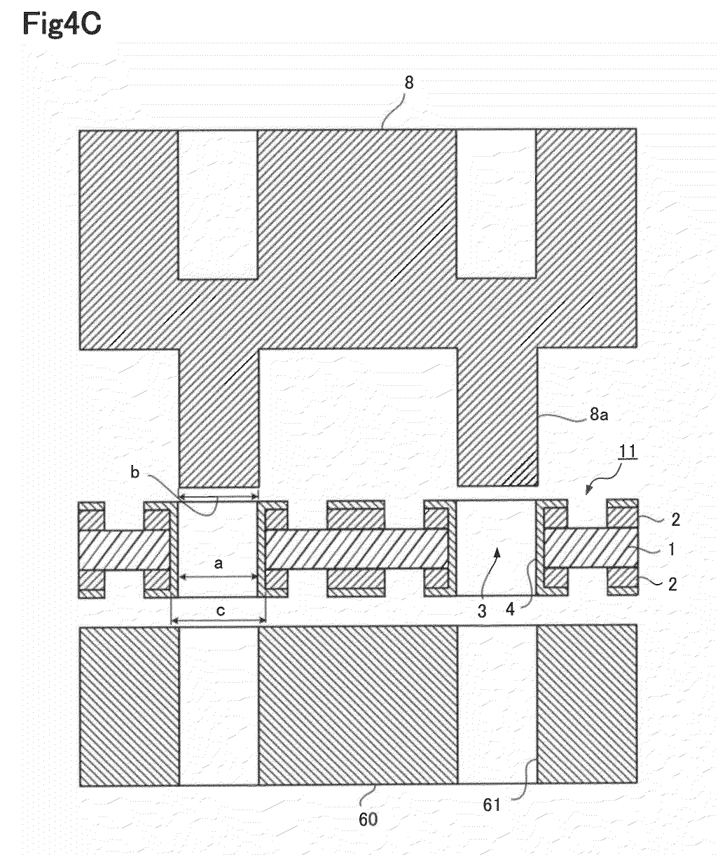

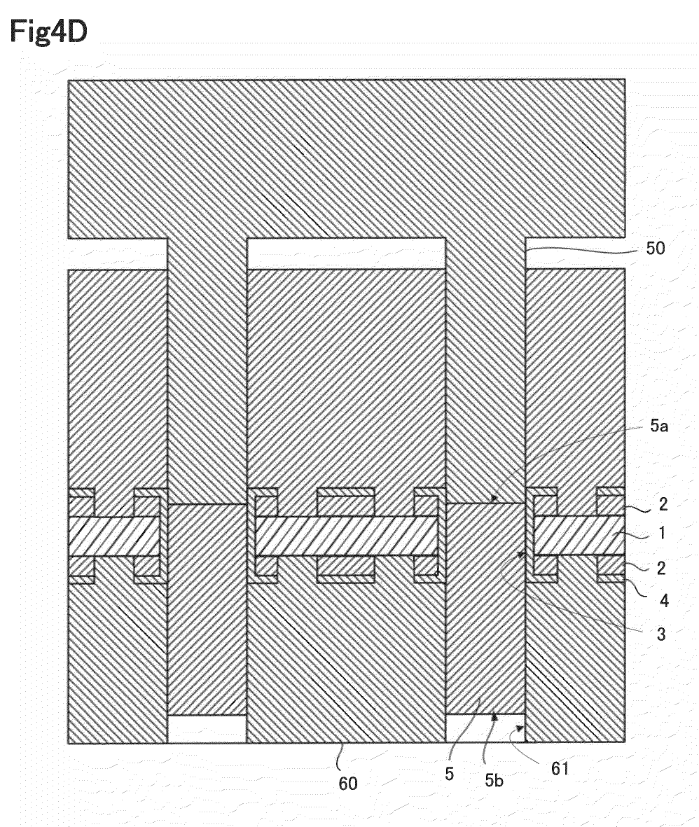

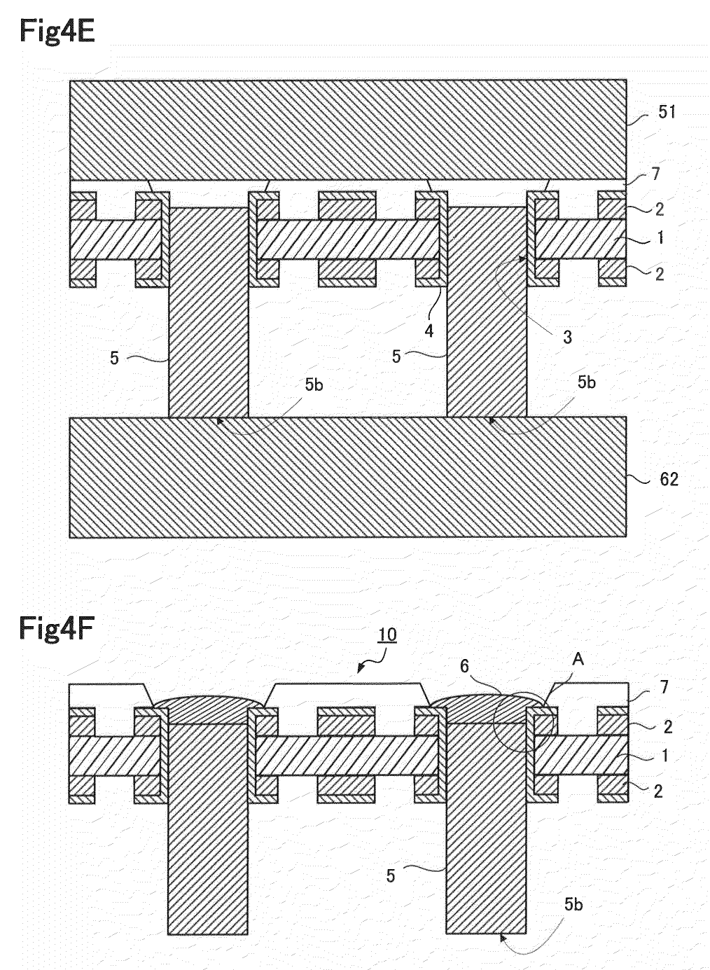

Next, a manufacturing method of the wiring substrate 10 having the above constitution is described with reference to the drawings. The manufacturing method described below is only an example, and the present invention is not limited to this example as long as the same results are obtainable. FIGS. 4A through 4F are drawings that illustrate the example manufacturing steps of the wiring substrate 10.

Beginning with FIG. 4A, a first step includes preparing a base material 8 for forming a metal post 5. The base material 8 is, for example, copper or an alloy having copper as the main component. In this example, the metal post 5 is formed from the base material 8 through a punching process. As shown in FIG. 4A, by sandwiching the base material 8 between a punch 50 and a die 60, the punch 50 is pushed into the base material 8 toward the die 60. The die 60 depicted in FIG. 4A includes two holes 61. Turning to FIG. 4B. portions of the base material 8 are punched into the holes 61 of the die 60 so as to create projecting parts 8a on the base material 8. As can be seen in FIG. 4B, instead of the punch 50 completely punching through the base material 8, the punching process is stopped while the projection part 8a is still connected to the base material 8.

A substrate 11 is depicted between the base material 8 and the die 60 in FIG. 4C. In this example, a substrate material 1 is prepared separately from the base material 8. For example, a substrate made from glass epoxy resin having a thickness of 200 um is used for the substrate material 1. A copper film, for example, is attached onto the surface of the substrate material 1, and wires 2 are formed through a patterning method such as photo-etching. A through-hole 3 is then opened in the position where a metal post 5 is to be implanted. A plated mask is formed through photolithography or the like on parts other than the parts where plating is applied, and a conductor 4 (through-hole conductor 4) is formed on the side wall in the through-hole 3 with, for example, a copper plate. The through-hole conductor 4 and the wires 2 are electrically connected so that the copper plate covers over the wires 2 around the through-hole 3.

As for the conductor 4 of the through-hole 3, the inner diameter (diameter of the internal space/through-hole opening or space defined by the conductor 4) thereof is formed with a tolerance so that the projection part 8a formed in the base material 8 is tightly fitted. As best illustrated in FIG. 4C, if the inner diameter of (the internal space/through-hole opening defined by) the through-hole conductor 4 is “a” and the outer diameter of the metal post 5 is “b,” and the hole diameter of the through-hole 3 (outer diameter of the through-hole conductor 4) is “c,” the dimensions of each element should at least satisfy the following relationship: a<b<c. If the outer diameter b of the metal post 5 is smaller than the inner diameter a of the through-hole conductor 4, the result is a medium or loose fit. If the outer diameter b of the metal post 5 is larger than the hole diameter (outer diameter of the through-hole conductor 4) c of the through-hole 3, the through-hole conductor 4 can be grated off when the metal post 5 is pressed in, and the metal post 5 and the through-hole conductor 4 will not come into face-to-face contact. Therefore, it can be beneficial to ensure that the thickness of the through-hole conductor 4 is greater than the tight fit tolerance with respect to the outer diameter b of the metal post 5.

As shown in FIG. 4C, the substrate 11 is placed on the die 60 so that the internal space/through-hole opening defined by the through-hole conductor 4 matches with the hole part 61 of the die 60. On the top thereof, the base material 8 is set so that the projection part 8a matches with the position of the through-hole conductor 4. As can be seen in FIG. 4D, a punch 50 is then pushed into the opening in the base material 8 that was formed when the projection part 8a was initial punched. The projection part 8a is punched out of the base material 8 so as to form the metal post 5, which is simultaneously pressed into the through-hole 3.

FIG. 4D is a cross-sectional drawing that illustrates a state in which the metal post 5 has been punched out and pressed into the through-hole 3. As shown in FIG. 4D, the metal post 5 that has been punched out is pressed into the through-hole 3 so that an end surface 5a of the metal post 5 remains positioned within the through-hole 3. As an example, the die 60 illustrated in FIG. 4D may have a hole 61 with a slightly larger diameter in comparison to the die that is to be used during punching as shown in FIG. 4A or FIG. 4B. Finally, when cutting off the metal post 5 from the base material 8, the through-hole conductor 4 works as a die.

FIG. 4E is a cross-sectional drawing that illustrates a step for aligning the end surfaces 5b of the metal posts 5. As can be seen in FIG. 4E, a solder resist 7 has been formed on portions of the surface of the substrate 11 where a solder 6 is not to be applied. The pattern of the solder resist 7 can be formed through photolithography or the like, for example. The side of the substrate 11 on which solder resist 7 has been formed is set on a tough and flat platen 51. The end surfaces 5b are then aligned on a single plane by pushing on the metal posts 5 that project from the substrate 11 with a jig 62. In another exemplary aspect, the steps for forming the solder resist and for aligning the end surfaces 5b of the metal posts 5 may be switched. In the state illustrated in FIG. 4D, where the metal post 5 has been pressed into the through-hole 3 of the substrate 11, if the end surfaces 5b of the metal posts 5 are aligned sufficiently to connect the semiconductor chips 20, a step for aligning the end surfaces 5b may be omitted.

FIG. 4F is a cross-sectional drawing of the wiring substrate 10 on which a solder has been formed on the end surface 5a of the metal post 5 that is in the through-hole conductor 4. Soldering is performed to complete the connection between the metal post 5 and the through-hole conductor 4 and to prevent the metal post 5 from coming off. A creamy solder is applied on the end surface 5a of the metal post 5 and soldering is performed between the metal post 5 and the through-hole conductor 4 by melting the solder 6 by heating the wiring substrate 10 in a reflow furnace. It is recommended that the creamy solder be inserted using a tube that is shaped like an injection needle to prevent bubbles from being generated inside. The solder enters the gap between the metal post 5 and the through-hole conductor 4, and both the electrical conductivity as well as the heat conductivity are further improved.

Instead of solder-joining the metal post 5 and the through-hole conductor 4, in another exemplary aspect, these two elements are joined by using an electrically conductive adhesive. In this example, the electrically conductive adhesive helps by filling in the gap between the metal post 5 and the through-hole conductor 4 in order to maintain the basic electrical conductivity between the metal post 5 and the through-hole conductor 4 through a face-to-face, metal-against-metal contact.

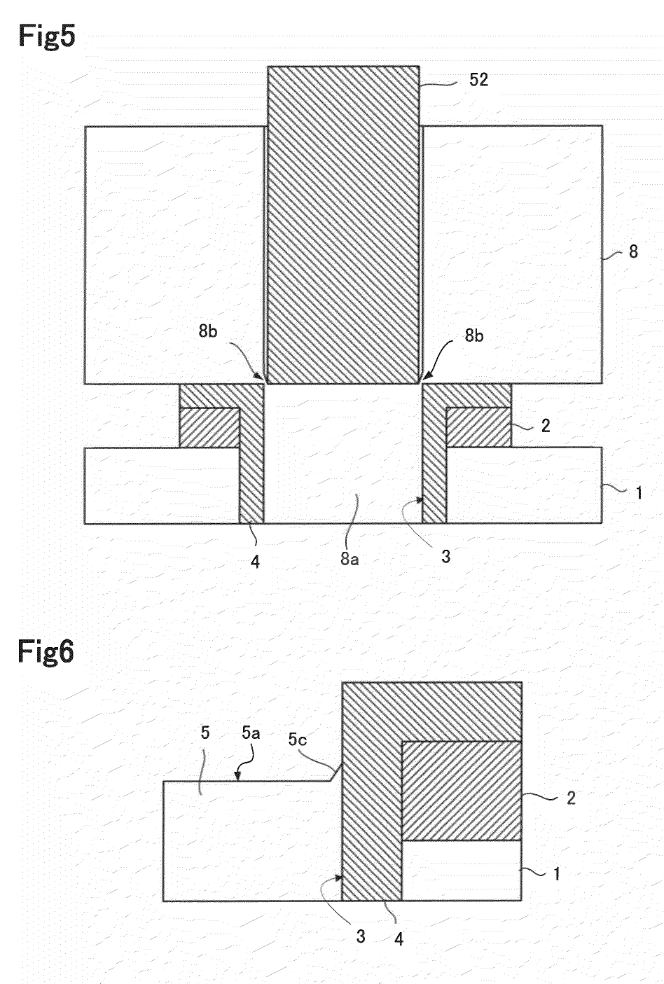

FIG. 5 is a cross-sectional schematic drawing that illustrates an exemplary aspect in which a diameter of a punch 52 that presses the metal post 5 into the through-hole conductor 4 is smaller than the diameter of the punch 50 that forms the projection part 8a. In FIG. 5, in order to facilitate understanding, hatching is not added to the base material 8 and the metal post 5. FIG. 6 is an enlarged cross-sectional drawing of detail A in FIG. 4F.

As illustrated in FIG. 5, if the diameter of the punch 52 that is used to punch the metal post 5 out of the base material 8 and press the metal post 5 into the through-hole conductor 4 is smaller than the diameter of the punch 50 that forms the projection part 8a, a peripheral part 8b on the base material side of the projection part 8a escapes into a gap between the punch 52 on the base material side 8a when the metal post 5 is cut off from the base material 8. As a result, as shown in FIG. 6, a burr 5c is formed at the peripheral rim of the end surface 5a of the metal post 5.

In this example, the burr 5c at the peripheral rim of the end surface 5a of the metal post 5 cuts into the through-hole conductor 4 when the end surfaces 5b of the metal posts 5 that project from the substrate 11 are aligned (such as by the alignment step discussed above with reference to FIG. 4E). Therefore, in this example, it is expected that the electrical connection between the metal post 5 and the through-hole conductor 4 will be reinforced while preventing the metal post 5 from detaching.

If, for example, the material of the through-hole conductor 4 is softer than the material of the die 60 that is used for a punching process, the shoulder part of the through-hole conductor 4 is dragged onto the side of the metal post 5 and becomes smooth during the punching out (cutting) and pressing steps that are illustrated in FIG. 4D. In this example, even if the diameter of the punch 50 for forming the projection part and the diameter of the punch 52 in the pressing step are the same, the burr 5c can still be formed in the peripheral rim of the end surface 5a of the metal post 5.

As for the wiring substrate related to the present invention, the metal post and the through-hole conductor are tightly fitted and the metal post and the conductor that is formed at the side wall of the through-hole are in face-to-face contact, and the electrical resistance and the thermal resistance in between are thus small and therefore stable against temperature changes. As a result, the reliability of the electrical conductivity of the wiring substrate and the heat cycle durability in heat conductivity are improved.

The embodiment disclosed herein is a non-restrictive example in every aspect. It is intended that the scope of the present invention include not only the above descriptions but also the equivalent meanings of the scope of the patent claims as well as all any changes made within the scope.

Obviously, numerous modifications and variations of the present invention are possible in light of the above teachings. It is therefore to be understood that within the scope of the appended claims, the invention may be practiced otherwise than as specifically described herein.

1. A wiring substrate for mounting electronic parts, comprising:
a substrate that includes a first surface, a second surface, and a plurality of through-holes that extend through said substrate from said first surface to said second surface so as to define a plurality of inner walls respectively;
an external conductor formed on at least one of said first surface or said second surface of said substrate;
a through-hole conductor formed on one of the plurality of inner walls of the through-holes so as to define a through-hole conductor space and so as to be electrically connected to the external conductor; and
a conductive post having first and second post ends, the first post end being positioned in the through-hole conductor space defined by the through-hole conductor such that the first post end is in contact with and is electrically connected to the through-hole conductor, and the second post end projecting out of said conductor space.

2. The wiring substrate according to claim 1, further comprising:
another through-hole conductor formed on another one of the plurality of inner walls of the through-holes so as to define another through-hole conductor space and so as to be electrically connected to the external conductor; and
another conductive post having another first and another second post ends, the another first post end being positioned in the another through-hole conductor space defined by the another through-hole conductor such that the another first post end is in contact with and is electrically connected to the another through-hole conductor, and the another second post end projecting out of said another conductor space, wherein the second post end and the another second post end project out of their respective conductor spaces to a position on a single plane.

3. The wiring substrate according to claim 1, wherein said conductive post is provided in the through-hole space such that said through-hole conductor and said conductive post make face-to-face contact along a surface of said conductive post between said first and second post ends.

4. The wiring substrate according to claim 1, wherein said first post end is positioned within the through-hole space such that a surface of said first post end is offset from a first distal end of the through-hole conductor space, and joined to said through-hole conductor by a conductive adhesive.

5. The wiring substrate according to claim 1, wherein a solder is interposed in a gap between said conductive post and said through-hole conductor.

6. The wiring substrate according to claim 1, wherein said conductive post and said through-hole conductor include a same metal as a main component.

7. The wiring substrate according to claim 1, wherein said conductive post includes a burr on a surface of said first post end.

8. The wiring substrate according to claim 1, wherein a diameter A of the through-hole space, an outer diameter B of said conductive post, and an inner diameter C of said through-hole satisfies the following relationship: A<B<C.

9. The wiring substrate according to claim 1, wherein said second post end includes a chamfered edge.

10. The wiring substrate according to claim 1, wherein the through-hole conductor includes a first distal surface that protrudes from the first surface of the substrate and a second distal surface that protrudes from the second surface of the substrate, and the through-hole conductor extends from the first distal surface to the second distal surface.

11. The wiring substrate according to claim 10, wherein the first post end is offset from the first distal surface of the through-hole conductor such that the first post end is positioned between the first distal surface of the through-hole conductor and the second distal surface of the through-hole conductor.

12. The wiring substrate according to claim 1, wherein the first post end is recessed from a first distal end of the through-hole conductor and the second post end projects from a second end of the through-hole conductor.

13. The wiring substrate according to claim 12, wherein a solder fills a gap between the first post end and first distal end of the through-hole conductor.

14. A manufacturing method of a wiring substrate comprising:
forming a through-hole conductor on an inner wall of a through-hole that has been formed in a substrate;
forming a column-shaped projection part by punching the column-shaped projection part out of a conductive base material such that the column-shaped projection part remains connected to the base material;
matching a position of said projection part and a through-hole opening defined by said through-hole conductor of said substrate;
forming a column-shaped post by punching out said column-shaped projection part from said base material while simultaneously pressing the column-shaped post into the through-hole opening defined by said through-hole conductor of said substrate; and
solder-joining an end part of said column-shaped post that has been pressed into the through-hole opening defined by said through-hole conductor to said through-hole conductor.

15. The manufacturing method of a wiring substrate according to claim 14, further comprising:
extending an end part of said column-shaped post that projects from the surface of said substrate to a projection distance substantially equal to an end part of at least one other column-shaped post that projects from the surface of said substrate.

16. The manufacturing method of a wiring substrate according to claim 14, wherein said forming the through-hole conductor includes forming the through-hole conductor by plating.

17. The manufacturing method of a wiring substrate according to claim 14, wherein said forming the through-hole conductor includes forming the through-hole conductor such that a diameter of the through-hole opening defined by said through-hole conductor is either smaller than or approximately equal in size to an outer diameter of said column-shaped post.

18. The manufacturing method of a wiring substrate according to claim 14, wherein said forming the column-shaped projection includes using a punch having a same diameter as a diameter of a punch used during said forming the column-shaped post.

19. The manufacturing method of a wiring substrate according to claim 14, wherein said forming the column-shaped projection includes using a punch having a larger diameter than a diameter of a punch used during said forming the column-shaped post.
